(19) United States
(12) Patent Application Publication
(10) Pub. No.: US 2023/0378163 A1
(43) Pub. Date: Nov. 23, 2023

(54) GAN POWER TRANSISTOR HAVING A VOLTAGE CLAMPING NODE WITH AVALANCHE CAPABILITY

(71) Applicant: The Hong Kong University of Science and Technology, Hong Kong (CN)

(72) Inventors: Jing CHEN, Hong Kong (CN); Gang LYU, Hong Kong (CN)

(21) Appl. No.: 18/177,918

(22) Filed: Mar. 3, 2023

Related U.S. Application Data
(60) Provisional application No. 63/345,023, filed on May 23, 2022.

(51) Int. Cl. H01L 27/02; H01L 27/06; H01L 29/20; H01L 29/778; H01L 21/02; H01L 29/66

(52) U.S. Cl. CPC H01L 27/0255; H01L 27/0605; H01L 29/2003; H01L 29/7786; H01L 21/02381; H01L 21/0254; H01L 21/0262; H01L 29/66462

(57) ABSTRACT

A semiconductor device with intrinsic avalanche capability is provided. The semiconductor device includes an engineered bulk silicon (EBUS) substrate having a first silicon layer and a second silicon layer formed above the first silicon layer, and a semiconductor heterostructure formed above the EBUS substrate. The semiconductor heterostructure comprises a high-side (HS) transistor and a low-side (LS) transistor. The HS transistor and the LS transistor are separated by a first isolation structure. The HS transistor has an input terminal (V_{IN}) electrically connected to a clamping diode formed at a first heterojunction between the first and second silicon layers. The clamping diode and the HS transistor are separated by a second isolation structure.

### CROSS REFERENCE TO RELATED APPLICATIONS

This application claims the benefit of U.S. Provisional Patent Application No. 63/345,023 filed on May 23, 2022, the disclosure of which is incorporated by reference herein in its entirety.

### FIELD OF THE INVENTION

The present disclosure generally relates to a semiconductor device. In particular, the present disclosure relates to an III-N heterostructure transistor fabricated on an engineered bulk silicon substrate with intrinsic avalanche capability.

### BACKGROUND OF THE INVENTION

Wide-bandgap GaN power transistors, especially in the form of planar high electron mobility transistor (HEMT) grown on a large-size silicon (Si) substrate and manufactured using Si-compatible processes, are being commercialized for power electronics that demand high efficiency and high power density via high-frequency operation. Monolithic integration of power devices and peripheral circuitry is expected to appreciably cut down the parasitic inductances from the interconnections in power and control loops of circuits and unlock the full high-frequency potential of the GaN power transistors [1], [2]. Tremendous efforts have been made to integrate a GaN power transistor with its peripheral functional blocks, such as gate drivers and/or protection circuits [3]. However, it is still elusive to monolithically integrate multiple high-voltage GaN HEMTs in a power switching circuit, e.g., a half-bridge circuit. A half-bridge circuit, comprising a high-side (HS) transistor and a low-side (LS) transistor, is an essential building block widely used in power converters.

Referring to FIGS. 1A-1C, the cross-sectional views of the half-bridge circuit 100 in three different termination schemes are depicted for illustrating the problems and deficiencies of the conventional design. The half-bridge circuit 100 is widely used in power converters, which comprises an HS transistor 100A and an LS transistor 100B, wherein the HS transistor 100A and the LS transistor 100B are HS GaN HEMT transistors formed on a conventional low-resistivity Si substrate. This arrangement is known as GaN on the Si platform. A transition layer 104 is formed on and adjacent to a substrate layer 102, which is usually a low-resistivity Si substrate. For high-voltage applications, the substrate layer 102 should be connected back to the local source terminal to avoid the back-gating effect. A nitride semiconductor buffer layer 106 (e.g., GaN) is grown on the transition layer 104. A nitride semiconductor barrier layer 110 (e.g., AlxGa1-xN, wherein 0<x≤1) is formed on the nitride semiconductor buffer layer 106. A passivation or gate dielectric layer 117 (e.g., SiN, AlN, Al₂O₃, etc.) is formed on the nitride semiconductor barrier layer 110. The wide-bandgap AlGaN/GaN heterostructure system of the nitride semiconductor barrier layer 110, induced by the spontaneous and piezoelectric polarization effects, yields two-dimensional electron gas (2DEG) channel 141 with a high sheet charge concentration and a high electron mobility. The 2DEG channel 141 is formed in the nitride semiconductor buffer layer 106 near the interface between the nitride semiconductor barrier layer 110 and the nitride semiconductor buffer layer 106. There are four ohmic contacts, including the LS source electrode 111, LS drain electrode 118, HS source electrode 119, and HS drain electrode 115. To realize a normally-off operation, a p-type layer 116 is optionally provided between the LS gate electrode 112 and the nitride semiconductor barrier layer 110. Similarly, another p-type layer 116 is optionally provided between the HS gate electrode 114 and the nitride semiconductor barrier layer 110. Other methods to realize a normally-off operation in GaN HEMTs, such as fluorine ion implantation technique, recessed gate structure with or without the gate dielectric, etc., may instead be adopted. The isolation region 108 between the HS transistor 100A and LS transistor 100B can be formed by multi-energy ion implantation, mesa technique, etc.

In a half-bridge circuit 100 based on a conventional GaN-on-Si platform, the LS source electrode 111 is usually connected to a low potential terminal (e.g., GND); the LS drain electrode 118 and the HS source electrode 119 are connected to the switching terminal (V_{SW}) 113; and the HS drain electrode 115 is connected to the input terminal (V_{IN}) of the half-bridge circuit. There are three termination schemes for the GaN half-bridge circuit. As shown in FIG. 1A, the first termination scheme is realized by connecting the LS source electrode 111 to the substrate layer 102 through a first metal contact 131. In FIG. 1B, the second termination scheme is realized by connecting the HS source electrode 119 (or LS drain electrode 118, not shown) is connected to the substrate layer 102 through a second metal contact 132. In FIG. 1C, the third termination scheme is realized by connecting the HS drain electrode 115 to the substrate layer 102 through a third metal contact 133. The substrate layer 102 can be biased to GND, V_{SW}, or V_{IN} respectively.

However, the half-bridge circuit 100 comprising the HS transistor 100A and the LS transistor 100B built on a conventional GaN-on-Si platform suffers severe crosstalk effects (i.e., back-gating effects and dynamic on-resistance degradation), that stems from the coupling through the commonly shared low-resistivity Si substrate [4], [5]. There is no effective isolation between the HS transistor 100A and the LS transistor 100B as they have the same low-resistivity Si substrate as the substrate layer 102.

To improve the crosstalk issue, the commercially available half-bridge GaN power integrated circuits (ICs) are generally implemented using a co-packaging approach characterized in that the HS transistor 100A and the LS transistor 100B are separated and co-packaged together. However, the co-packaged power IC is bulky and the parasitic inductances are still significantly high. With the increasing demand for high-frequency and high-power switching applications, parasitic inductance may limit the switching speed and power handling capability, leading to reduced performance. Therefore, the problem of the parasitic inductance in GaN half-bridge circuits is a critical challenge for unlocking the high-frequency applications.

Another possible solution was proposed by the inventor of the present invention, J. Chen [6], which utilizes silicon on insulator (SOI) wafer together with isolation structures. Each power switch has a local substrate that is isolated from the supporting wafer by oxide layers on the sides and at the bottom. Therefore, the HS transistor 100A and the LS transistor 100B are separated from each other and from the substrate layer 102. The SOI substrate provides effective isolation, but also has serious drawbacks in substantially higher substrate cost and very challenging thermal and strain management.

Another deficiency of the typical GaN HEMTs is the lack of avalanche capability (i.e., the capability of releasing energy at high blocking voltage) due to the absence of PN junctions in the high field region and relatively weak impact ionization coefficients. This results in a weak unclamped inductive switching (UIS) capability [7]. This drawback has hindered the use of the GaN HEMT power transistors in motor-drive applications, which prefer the use of power switches with avalanche capability for withstanding the energy at high voltage. If avalanche capability is absent, there will be a demand for compromising the gate driving speed (e.g., lower di/dt during the turn-off) to suppress the inductive switching over-voltage.

Accordingly, there is a need in the art to have a low-cost GaN power transistor having an auxiliary voltage clamping node with intrinsic avalanche capability. Furthermore, other desirable features and characteristics will become apparent from the subsequent detailed description and the appended claims, taken in conjunction with the accompanying drawings and this background of the disclosure.

### SUMMARY OF THE INVENTION

Provided herein is a semiconductor device with intrinsic avalanche capability and the method for fabricating the same. It is the objective of the present disclosure to provide a half-bridge circuit for high-voltage applications that can eliminate the crosstalk and improve the avalanche capability.

In the first aspect of the present disclosure, there is provided that a semiconductor device includes an engineered bulk silicon (EBUS) substrate having a first silicon layer and a second silicon layer formed above the first silicon layer, and a semiconductor heterostructure formed above the EBUS substrate. The semiconductor heterostructure comprises a high-side (HS) transistor and a low-side (LS) transistor. The HS transistor and the LS transistor are separated by a first isolation structure. The HS transistor has an input terminal (V_{IN}) electrically connected to a clamping diode formed at a first heterojunction between the first and second silicon layers. The clamping diode and the HS transistor are separated by a second isolation structure.

In an embodiment, the first and second isolation structures divide the second silicon layer into a first silicon island positioned under the LS transistor, a second silicon island positioned under the HS transistor, and a third silicon island not overlying with the HS transistor.

In an embodiment, a first diode is formed at a second heterojunction between the first silicon island and the first silicon layer. A second diode is formed at a third heterojunction between the second silicon island and the first silicon layer. The clamping diode is formed between the third silicon island and the first silicon layer.

In an embodiment, the third silicon island is electrically connected to the input terminal (V_{IN}) at an auxiliary voltage clamping node by a third via hole for protecting the HS transistor. The auxiliary voltage clamping node is connected to an HS drain electrode of the HS transistor.

In one embodiment, the first silicon island is electrically connected to a low potential terminal by a first via hole. The second silicon island is electrically connected to a switching terminal (V_{SW}) by a second via hole. The first diode and the second diode are arranged between the switching terminal (V_{SW}) and the low potential terminal in a back-to-back manner to provide an avalanche breakdown function.

In an embodiment, the first silicon layer is an N-type silicon layer; and the second silicon layer is a P-type silicon layer.

In an embodiment, the first and the second isolation structures are deep trench isolation structures filled with dielectric materials. The deep trench isolation structures are extended vertically deep enough to at least divide the second silicon layer into the first silicon island, the second silicon island, and the third silicon island.

In an embodiment, the first and the second isolation structures each has a depth and a width tuned to modulate an avalanche breakdown voltage. The depth and the width affect a crowded electrical field along isolation trench sidewalls.

In an embodiment, the EBUS substrate further includes a dielectric layer provided below the first silicon layer.

In an embodiment, the EBUS substrate further includes a mechanical substrate provided below the first silicon layer, wherein a Schottky contact is formed between the mechanical substrate and the first silicon layer.

In another embodiment, the EBUS substrate further includes a third silicon layer formed at a backside of the first silicon layer, thereby a PNP doping profile is formed from the second silicon layer to the third silicon layer. The third silicon layer is a P-type silicon layer.

In an embodiment, the semiconductor heterostructure is an III-N semiconductor heterostructure having a transition layer, a buffer layer, and a barrier layer. The buffer layer is formed on and adjacent to the transition layer. The barrier layer is formed on and adjacent to the buffer layer. The buffer layer and the barrier layer form a heterojunction, and the buffer layer has a channel layer including a 2-dimensional electron gas (2DEG) channel formed near an interface between the barrier layer and the buffer layer.

In an embodiment, the transition layer is a Gallium Nitride (GaN) layer and the buffer layer is an Aluminium Gallium Nitride (AlGaN) layer.

In an embodiment, a plurality of ohmic contacts are deposited above the barrier layer to form an LS drain electrode, an LS source electrode, an HS drain electrode, an HS source electrode, and an auxiliary voltage clamping node. The auxiliary voltage clamping node is electrically connected to the HS drain electrode and is not overlying with the HS transistor for protecting the HS transistor by providing an over-voltage protection through the clamping diode positioned below the auxiliary voltage clamping node.

In an embodiment, the semiconductor heterostructure is a standalone heterostructure transistor or a monolithic integrated heterostructure transistor.

In the second aspect of the present disclosure, there is provided a method for fabricating a semiconductor device having an III-N semiconductor heterostructure formed above an EBUS substrate with an intrinsic avalanche capability. The method includes the steps of depositing a mechanical substrate on a backside of an N-type silicon layer; forming a P-type silicon layer above the N-type silicon layer by performing boron implantation into the N-type silicon layer or by performing Si epitaxial deposition; depositing a transition layer of an III-N semiconductor material above the P-type silicon layer; depositing a buffer layer of AlGaN above the transition layer by performing metal-organic chemical vapor deposition; depositing a barrier layer above the buffer layer; depositing a plurality of ohmic contacts above the barrier layer to form an LS drain electrode, an LS source electrode, an HS drain electrode, an HS source electrode, and an auxiliary voltage clamping node; performing etching from the barrier layer to a predetermined depth exceeding the P-type silicon layer to form a first isolation structure and a second isolation structure for segmenting the P-type silicon layer into a plurality of silicon islands, wherein the first isolation structure is positioned between the LS drain electrode and the HS source electrode, and the second isolation structure is positioned between the HS drain electrode and the auxiliary voltage clamping node; filling the first isolation structure and the second isolation structure with a dielectric material; and forming a plurality via holes to establish electrical conductivity from the plurality of silicon islands to the LS source electrode, the HS source electrode, and the auxiliary voltage clamping node.

In an embodiment, the forming of the P-type silicon layer above the N-type silicon layer further includes performing high-temperature annealing process and thermal diffusion or epitaxy growth to re-distribute dopants of boron throughout the P-type silicon layer.

In an embodiment, the method further includes connecting the LS drain electrode and the HS source electrode together as a switching terminal (V_{SW}) of a half-bridge circuit; connecting the LS source electrode to a low potential terminal; and connecting the HS drain electrode and the auxiliary voltage clamping node together to an input terminal (V_{IN}) of the half-bridge circuit.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Other aspects and advantages of the present invention are disclosed as illustrated by the embodiments hereinafter.

### BRIEF DESCRIPTION OF THE DRAWINGS

The appended drawings contain figures to further illustrate and clarify the above and other aspects, advantages, and features of the present disclosure. It will be appreciated that these drawings depict only certain embodiments of the present disclosure and are not intended to limit its scope. It will also be appreciated that these drawings are illustrated for simplicity and clarity and have not necessarily been depicted to scale. The present disclosure will now be described and explained with additional specificity and detail through the use of the accompanying drawings in which:

FIG. 1A is a cross-sectional view of a conventional half-bridge circuit in the first termination scheme;

FIG. 1B is a cross-sectional view of a conventional half-bridge circuit in the second termination scheme;

FIG. 1C is a cross-sectional view of a conventional half-bridge circuit in the third termination scheme;

FIG. 2 is a typical circuit diagram illustrating the use of power switches for driving an electric motor;

FIG. 3 is a circuit diagram that corresponds to an example half-bridge circuit, in accordance with certain embodiments of the present disclosure;

FIG. 4A is a cross-sectional view of the half-bridge circuit conceptually illustrating the diodes formed at the heterojunctions, in accordance with certain embodiments of the present disclosure;

FIG. 4B is a cross-sectional view of the half-bridge circuit showing the silicon islands, in accordance with certain embodiments of the present disclosure;

FIG. 5A is a second embodiment of the EBUS substrate, in accordance with certain embodiments of the present disclosure;

FIG. 5B is a third embodiment of the EBUS substrate, in accordance with certain embodiments of the present disclosure;

FIG. 6A is a comparison between the conventional half-bridge circuit and the present disclosure when the HS transistor is ON and the LS transistor is OFF;

FIG. 6B is a comparison between the conventional half-bridge circuit and the present disclosure when the HS transistor is OFF and the LS transistor is ON;

FIG. 6C is a comparison in the drain current between the conventional half-bridge circuit and the present disclosure;

FIG. 7A shows the circuit diagram of the present disclosure and the corresponding I-V curve when the HS transistor is OFF and the LS transistor is ON; and

FIG. 7B shows the circuit diagram of the present disclosure and the corresponding I-V curve when the HS transistor is ON and the LS transistor is OFF.

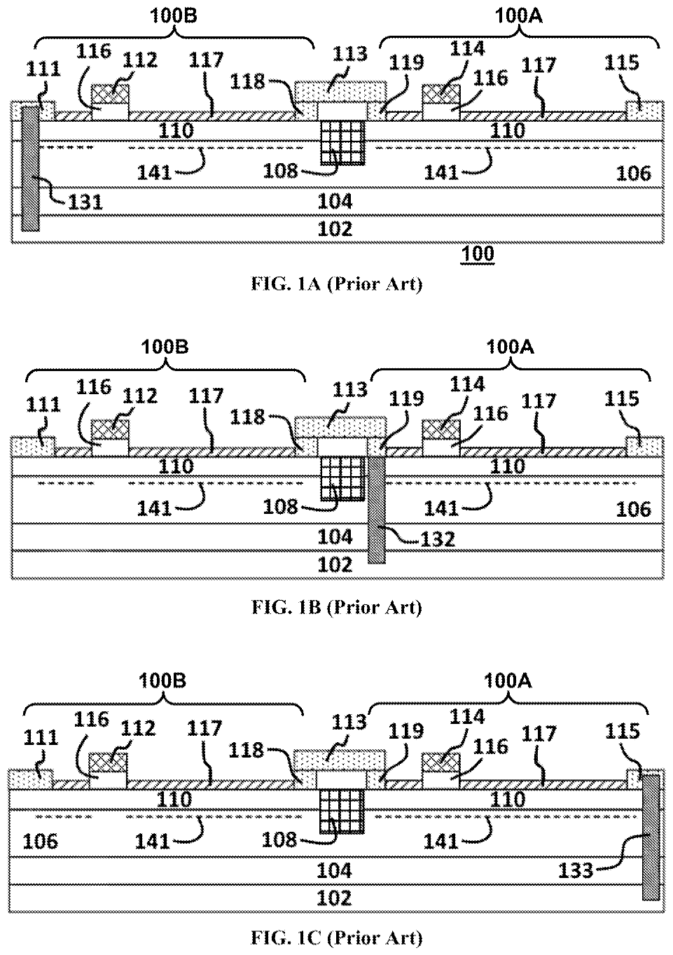

### DETAILED DESCRIPTION OF THE INVENTION

The present disclosure generally relates to a gallium nitride (GaN) power transistor having an auxiliary voltage clamping node with avalanche capability. It is one of the objectives of the present disclosure to provide a GaN half-bridge circuit with reduced parasitic inductances for achieving high-performance, reliable, and cost-effective switching applications.

The benefits, advantages, solutions to problems and any element(s) that may cause any benefit, advantage, or solution to occur or become more pronounced are not to be construed as critical, required, or essential features or elements of any or all of the claims. The invention is defined solely by the appended claims including any amendments made during the pendency of this application and all equivalents of those claims as issued.

In the claims which follow and in the preceding description of the invention, except where the context requires otherwise due to express language or necessary implication, the word “comprise” or variations such as “comprises” or “comprising” is used in an inclusive sense, i.e., to specify the presence of the stated features but not to preclude the presence or addition of further features in various embodiments of the invention.

As used herein and in the claims, the term “connect” refers to electrical connection either directly or indirectly via one or more electrical means unless otherwise stated. The values recited herein are exemplary, and are not intended to limit the present invention to a particular configuration or set of values, but only indicate one possible set of values, unless otherwise indicated herein.

As used herein throughout the specification, notations N+, N, P+, and P indicate relative levels of impurity concentration in each conductivity type. That is, N+ indicates an N-type impurity concentration higher than that of N, and P+ indicates a P-type impurity concentration higher than that of P. For simplicity and clarity, an N+ type is sometimes referred to as an N-type, and a P+ type is sometimes referred to as a P-type.

As used herein, the terms “above”, “below”, “topside”, “backside”, and the like describe the relative vertical position of the layers or regions to each other, which encompasses the orientations depending on the spatial orientation of the semiconductor device. Generally, a first layer being above a second layer refers to the position of the first layer that is further away from the bulk vertically.

Various embodiments disclosed herein provide a structure and/or a fabrication method (e.g., manufacturing method) for an improved semiconductor device that includes a semiconductor heterostructure and an engineered bulk silicon (EBUS) substrate. In a preferred embodiment, the semiconductor heterostructure is an III-N semiconductor heterostructure (e.g., gallium nitride (GaN), aluminum nitride (AlN), indium nitride (InN), etc.). It is apparent that the semiconductor heterostructure may otherwise be a standalone heterostructure transistor or a monolithic integrated heterostructure transistor without departing from the scope and spirit of the present disclosure. As used herein and in the claims, the EBUS is a type of silicon substrate that has been engineered to have performance optimized for specific applications. The EBUS provides a platform for the semiconductor heterostructure to grow on, so the semiconductor heterostructure and the EBUS substrate are fabricated monolithically. For instance, the improved semiconductor device can include a single simple AlGaN/GaN heterostructure as a gate-controlled channel for the semiconductor device. The advantage of the fusion of the semiconductor heterostructure with the silicon-based substrate allows the semiconductor device to process the unique properties of the semiconductor heterostructure while leveraging the cost-effectiveness of the silicon fabrication process. Furthermore, the EBUS substrate can be employed to deliver the functionality of eliminating the crosstalk and improving the avalanche capability for the semiconductor device simultaneously. In particular, the present disclosure improves the existing GaN on EBUS power IC platform by built-in Si PN junctions for providing an intrinsic avalanche capability, which is known to be lacking in GaN lateral HEMTs.

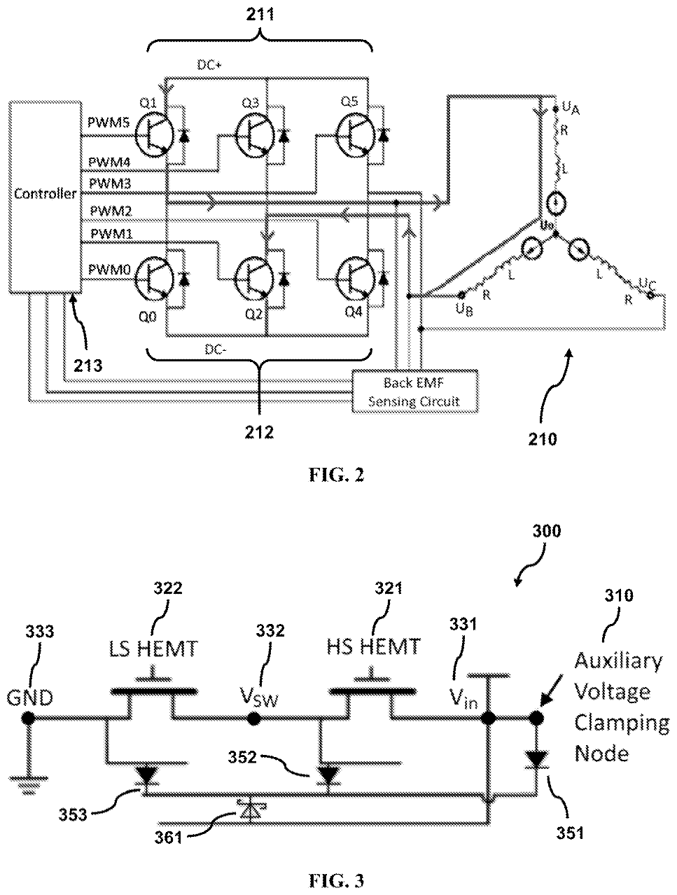

FIG. 2 shows a typical circuit diagram of an electric motor 210 and the power switches for controlling the electric motor 210. The power switches include three HS transistors 211 (Q₁, Q₃, Q₅) and three LS transistors 212 (Q₀, Q₂, Q₄). The power switches are controlled by a controller 213 using pulse width modulation (PWM) signals. Preferably, the power switches require to have avalanche capability for protecting the power switches from high voltage and current transients when switching the electric motor 210. The term “avalanche capability” refers to the capability of the transistor in withstanding high energy during an electrical avalanche. Without an avalanche capability, failure may occur in the power switch when a voltage significantly greater than the operating voltage of the transistor flows into the transistor, which may damage the power switch at such extremely high voltages. As GaN HEMT has high electron mobility and small terminal capacitance, it can be used to design a power switch with high switching speed, ideally for electric motor 210. However, conventional GaN HEMTs have some drawbacks with respect to the lack of avalanche capability due to the absence of PN junctions in the high field region. When avalanche is lacking, a compromise is needed to be made in gate driving speed to mitigate the inductive switching over-voltage.

FIG. 3 shows a circuit diagram of a half-bridge circuit 300 with an HS transistor (e.g., HS GaN HEMT) 321 and an LS transistor (e.g., LS GaN HEMT) 322 with intrinsic avalanche capability, in accordance with certain embodiments of the present disclosure. In particular, the present invention provides a GaN on EBUS power IC platform, which features monolithic integration of the HS transistor 321 and the LS transistor 322 to form the half-bridge circuit 300. The source electrode of the LS transistor 322 is usually connected to a low potential terminal (e.g., GND) 333, the drain electrode of the LS transistor 322 and the source electrode of the HS transistor 321 are connected to the switching terminal (V_{SW}) 332; the drain electrode of the HS transistor 321 is connected to the input terminal (V_{IN}) 331 of the half-bridge circuit 300. Advantageously, the half-bridge circuit 300 includes a bulk Si substrate engineered into a PN junction embedded substrate. The Si PN junction possesses high voltage blocking capability with avalanche capability. Therefore, the EBUS can simultaneously provide the half-bridge circuit 300 with an avalanche breakdown function and deliver the functionality of eliminating the crosstalk between the HS transistor 321 and the LS transistor 322. In certain embodiments, the HS transistor 321 has the input terminal (V_{IN}) 331 electrically connected to a clamping diode 351 via an auxiliary voltage clamping node 310 for protecting the HS transistor 321 by providing an over-voltage protection. The low potential terminal 333 is electrically connected to a first diode 351, and the switching terminal (V_{SW}) 332 is electrically connected to a second diode 352, thereby the first diode 351 and the second diode 352 are arranged in a back-to-back manner to provide an avalanche breakdown function. The clamping diode 351 and the first and second diodes 351, 352 are connected to the input terminal (V_{IN}) 331 via a Schottky contact 361.

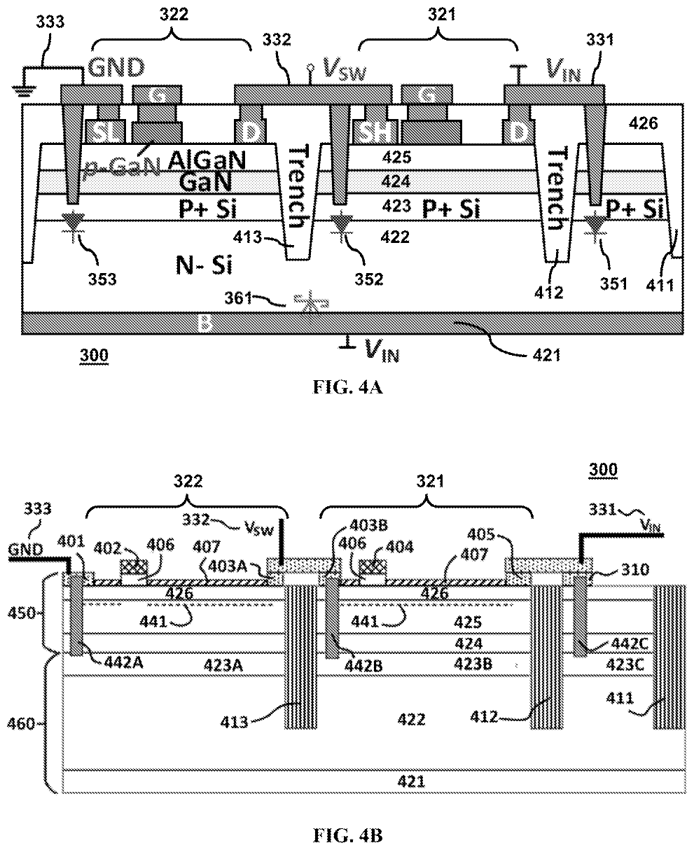

Referring to FIGS. 4A and 4B, the cross-sectional views of the half-bridge circuit 300 in accordance with one or more embodiments of the present disclosure is provided. The semiconductor device of the half-bridge circuit 300 comprises an EBUS substrate 460 and an III-N semiconductor heterostructure 450 formed above the EBUS substrate 460.

In certain embodiments, the EBUS substrate 460 comprises a mechanical substrate 421, a first silicon layer 422, and a second silicon layer 423. The mechanical substrate 421 may be a metal layer (e.g., aluminum, copper, etc.) provided below the first silicon layer 422, or a metal contact layer of the back-end-of-line (BEOL) process. Other possible materials for the mechanical substrate 421 may include but not limited to, sapphire, silicon carbide (SiC), or a heavily doped p-type silicon. The first silicon layer 422 is an N-type silicon layer with a relatively low doping concentration (ND), such as 2×10¹³. The second silicon layer 423 is a P-type silicon layer formed on the first silicon layer 422. The second silicon layer 423 has a higher doping concentration (NA), such as 2×10¹⁸. The highly doped p-type layer is used in the second silicon layer 423 for the growth of nitride heterostructure because of its strong mechanical strength. On the lower end, a Schottky contact 361 can be formed between the mechanical substrate 421 and the first silicon layer 422, while the mechanical substrate 421 should be connected to the input terminal (V_{IN}) 331 of the half-bridge circuit 300. Alternatively, an ohmic contact (not shown in the figures) can be formed between the mechanical substrate 421 and the first silicon layer 422. In a non-limiting example, the isolation capability of the PN junctions between the first silicon layer 422 and the second silicon layer 423 in the EBUS substrate 460 is sufficient for supporting high-voltage applications (e.g., electric motor-drive).

In certain embodiments, the III-N semiconductor heterostructure 450 may comprise a transition layer 424, a buffer layer 425, a barrier layer 426, and/or a passivation layer 407. The transition layer 424 can be formed on and adjacent to the EBUS substrate 460. For example, the transition layer 424 can be located above the second silicon layer 423. The buffer layer 425 can be formed on and adjacent to the transition layer 424. In one embodiment, the buffer layer 425 is an III-N semiconductor layer (e.g., GaN, AlGaN, InAlN, etc.), and can be located above the transition layer 424. The barrier layer 426 can be formed on and adjacent to the buffer layer 425. In one embodiment, the barrier layer 426 is also an III-N semiconductor layer (e.g., GaN, AlGaN, InAlN, etc.), and can be located above the buffer layer 425. In the illustrated embodiments, it is provided that the transition layer 424 is a GaN layer and the buffer layer 425 is an Aluminium Gallium Nitride (AlGaN) layer. The buffer layer 425 and the barrier layer 426 form a heterojunction, wherein the buffer layer 425 has a channel layer including a 2-dimensional electron gas (2DEG) channel 441. In particular, the 2DEG channel 441 is formed in the buffer layer 425 near an interface between the barrier layer 426 and the buffer layer 425.

A person skilled in the art should readily recognize from the cross-sectional views of FIGS. 4A and 4B that an HS transistor 321 and an LS transistor 322 of the III-N semiconductor heterostructure 450 are illustrated, including the associated gate, source, and drain. On the barrier layer 426, plural ohmic contacts are provided. There are four ohmic contacts, including the LS source electrode 401, LS drain electrode 403A, HS source electrode 403B, and HS drain electrode 405.

The LS transistor 322 can be switched between ON or OFF by controlling the LS gate electrode 402, and the HS transistor 321 can be switched between ON or OFF by controlling the HS gate electrode 404. The LS gate electrode 402 and the HS gate electrode 404 may be an ohmic type electrode or a Schottky type electrode. To realize a normally-off operation, a p-type layer 406 (such as a p-GaN) is optionally provided between the LS gate electrode 402 and the barrier layer 426. Similarly, another p-type layer 406 (such as a p-GaN) is optionally provided between the HS gate electrode 404 and the barrier layer 426. Other methods to realize a normally-off operation in the III-N semiconductor heterostructure 450, such as fluorine ion implantation technique, recessed gate structure with or without the gate dielectric, etc., may instead be adopted without departing from the scope and spirit of the present disclosure.

In certain embodiments, the LS source electrode 401 is connected to a low potential terminal 333; the LS drain electrode 403A and the HS source electrode 403B are connected to the switching terminal (V_{SW}) 332; and the HS drain electrode 405 is connected to the input terminal (V_{IN}) 331.

In certain embodiments, isolation structures 411, 412, 413 are formed by carving out the III-N semiconductor heterostructure 450 and part of the EBUS substrate 460. The isolation structures 411, 412, 413 are extended vertically to a depth deep enough to at least divide the second silicon layer 423 into a plurality of local P-type silicon layers, wherein the plurality of local P-type silicon layers may include a first silicon island 423A, a second silicon island 423B, and a third silicon island 423C. In one example, the isolation structures 411, 412, 413 are deep trench isolation structures filled with dielectric materials (e.g., oxide, nitride, or polyimide, etc.). In particular, the HS transistor 321 and the LS transistor 322 are separated by a first isolation structure 413. As explained above, the HS drain electrode 405 of the HS transistor 321 is electrically connected to a clamping diode 351 via an auxiliary voltage clamping node 310 for protecting the HS transistor 321. The clamping diode 310 is separated from the HS transistor 321 by a second isolation structure 412. The third isolation structure 411 is used to separate one half-bridge circuit 300 from another. It is further noted that the isolation structures 411, 412, 413 may be extended vertically to the same depth or different depth, subject to the design requirements. The deep trench isolation structures have the depth and the width tuned to modulate the avalanche breakdown voltage. Such changes in depth and width will affect the crowded electrical field at the corners of the PN junction along the isolation trench sidewalls. It is also apparent that the third isolation structure 411 may extend completely through the EBUS substrate 460 without departing from the scope and spirit of the present disclosure.

By dividing the second silicon layer 423, advantageously, the first silicon island 423A is positioned under the LS transistor 322, the second silicon island 423B is positioned under the HS transistor 321; and the third silicon island 423C is not overlying with the HS transistor 321. With the heterojunction between the first silicon layer 422 and the second silicon layer 423, diodes can be formed at the PN junctions. Particularly, a clamping diode 351 is formed at a first heterojunction between the third silicon island 423C and the first silicon layer 422. A first diode 353 is formed at a second heterojunction between the first silicon island 423A and the first silicon layer 422. A second diode 352 is formed at a third heterojunction between the second silicon island 423B and the first silicon layer 422. The cathodes of the above three diodes are all connected to the first silicon layer 422.

In order to appropriately bias the voltage at the anodes of the three diodes, the plurality of local P-type silicon layers are connected to the ohmic contacts above the barrier layer 426. In certain embodiments, a plurality of via holes are used to electrically connect the ohmic contacts to the plurality of local P-type silicon layers underneath. In the illustrated embodiments, the first silicon island 423A is electrically connected to the low potential terminal 333 at the LS source electrode 401 by a first via hole 442A. The second silicon island 423B is electrically connected to the switching terminal (V_{SW}) 332 at the HS source electrode 403B by a second via hole 442B. The third silicon island 423C is electrically connected to the input terminal (V_{IN}) 331 at the auxiliary voltage clamping node 310 by a third via hole 442C. As the auxiliary voltage clamping node 310 is connected to the HS drain electrode 405 of the HS transistor 321, the clamping diode 351 provided between the third silicon island 423C and the first silicon layer 422 can protect the HS transistor 321. Particularly, the auxiliary voltage clamping node 310 is not overlying with the HS transistor 321 for protecting the HS transistor 321 by providing an over-voltage protection through the clamping diode 351 positioned below the auxiliary voltage clamping node 310.

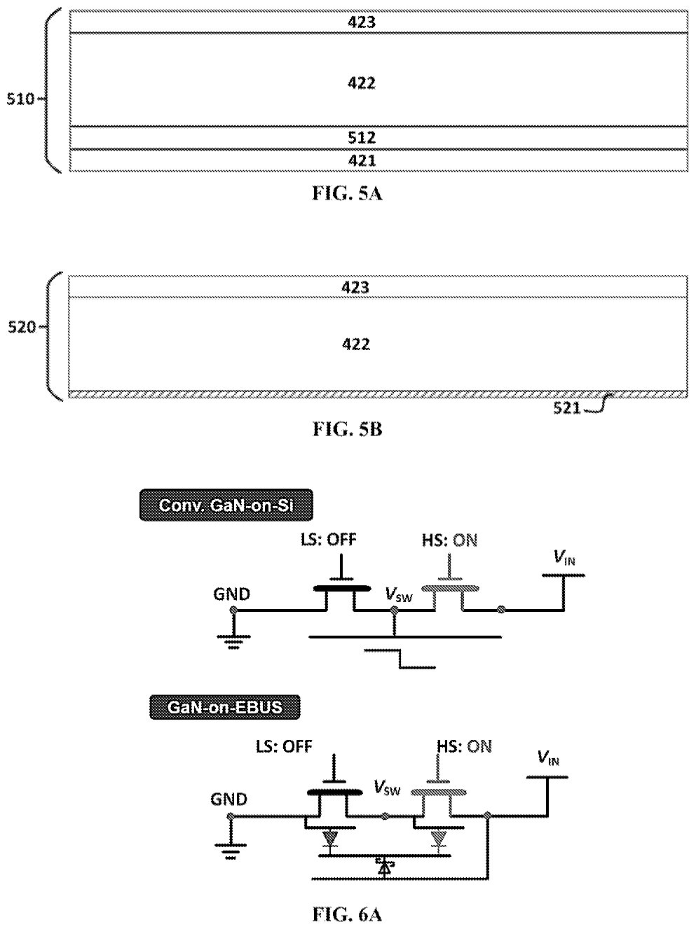

FIG. 5A shows a second embodiment of the EBUS substrate 510, in accordance with certain embodiments of the present disclosure. The EBUS substrate 510 can be a variation for replacing the EBUS substrate 460 of FIGS. 4A-4B. In this variation, the first silicon layer 422 is an N-type silicon layer having a P+ implantation on the topside of the first silicon layer 422 to form the second silicon layer 423, and another P+ implantation on the backside of the first silicon layer 422 to form the third silicon layer 512 (P-type silicon layer). Therefore, the first silicon layer 422 is sandwiched between the second silicon layer 423 and the third silicon layer 512. A PNP doping profile can be formed from the second silicon layer 423 to the third silicon layer 512 of the EBUS substrate 510 in the second embodiment. A mechanical layer 421 may be provided below the third silicon layer 512, which is connected to the input terminal (V_{IN}) 331 or to the low potential terminal (e.g., GND) 333, when being implemented in a half-bridge circuit. The mechanical layer 421 can be connected to the third silicon layer 512 in the form of an Ohmic contact or a Schottky contact.

FIG. 5B shows a third embodiment of the EBUS substrate 520, in accordance with certain embodiments of the present disclosure. The EBUS substrate 520 can be another variation for replacing the EBUS substrate 460 of FIGS. 4A-4B. In this variation, the first silicon layer 422 is an N-type silicon layer and the backside of the first silicon layer 422 is terminated by a dielectric layer 523 (e.g., an oxide layer, a nitride layer, or a polyimide layer, etc.). The topside of the first silicon layer 422 is implanted with a P-type silicon layer 524. The dielectric layer 523 is provided below the first silicon layer 422 and connected to the input terminal (V_{IN}) 331 or to the low potential terminal (e.g., GND) 333, when being implemented in a half-bridge circuit.

The method for fabricating the semiconductor device of the present disclosure is described herein. The semiconductor device has an III-N semiconductor heterostructure formed above an EBUS substrate with an intrinsic avalanche capability. The first step is to prepare the EBUS substrate 460 for the III-N semiconductor heterostructure 450 to be formed above the EBUS substrate 460. The EBUS substrate 460 may be prepared by first depositing a mechanical substrate 421 on a backside of an N-type silicon layer (first silicon layer 422). In certain embodiments, the mechanical substrate 421 may be a P-type substrate, which is formed by performing boron implantation into the first silicon layer 422 from the backside. Alternatively, the mechanical substrate 421 may be a metal contact layer, which is formed in a BEOL process. On the topside of the N-type silicon layer, a P-type silicon layer (second silicon layer 423) is formed by performing boron implantation into the N-type silicon layer followed by performing high-temperature (e.g., >1000° C.) annealing process for dopant activation and performing thermal diffusion. Alternatively, the second silicon layer 423 may be formed by performing Si epitaxial deposition (e.g., vapor-phase epitaxy). In the case of boron implantation, a precisely controlled boron implantation can create P-type regions within the N-type silicon layer. The boron atoms replace some of the silicon atoms in the crystal lattice and create a PN junction within the N-type silicon layer. After boron implantation, thermal annealing is performed to activate the dopants of boron, i.e., facilitate the movement of dopants from interstitial sites to Si substitutional sites. Thermal diffusion takes place during the annealing process, and results in certain degree of dopants re-distribution throughout the P-type silicon layer and create a uniform dopant distribution profile as well as a low-resistivity P-type layer.

After preparing the EBUS substrate 460, the III-N semiconductor heterostructure 450 is formed on the topside. The III-N semiconductor heterostructure is created by, but not limited to, an epitaxy process in the depletion-mode (D-mode) transistors or the enhancement-mode (E-mode) transistors, which may include p-GaN gate HEMTs, metal-insulator-semiconductor field-effect transistors (MISFET) or metal-oxide-semiconductor FET (MOSFET). Taking the p-GaN gate HEMT as an example, the first step to form the III-N semiconductor heterostructure is to deposit a transition layer 424 of an III-N semiconductor material above the P-type silicon layer from the EBUS substrate 460. Next, a buffer layer 425 is deposited above the transition layer. As the transition layer 424 is preferably GaN, and the buffer layer 425 is AlGaN, the deposition is performed by metal-organic chemical vapor deposition or Metal Beam Evaporation (MBE) method. A barrier layer 426 should further be deposited on top of the buffer layer 425, so that a channel including a 2DEG channel 441 can be formed at an interface between the buffer layer 425 and the barrier layer 426. Then a p-GaN layer 406 is deposited to fabricate a p-GaN gate HEMT. In the case of metal-insulator-semiconductor HEMT, the p-GaN layer 406 can be formed in the manner of dielectric layers, such as SiO2, SiNx, aluminum oxide (Al₂O₃) or other high-dielectric-constant (high-k) oxide with or without recess-etching into the barrier layer 426. The device fabrication method includes, but not limited to, conventional fabrication methods of conventional D-mode GaN HEMTs or E-mode GaN HEMTs that include p-GaN gate HEMT, MISFET, MOSFET. Taking the p-GaN gate HEMT as an example, the p-GaN gate 406 is firstly formed by inductively coupled plasma (ICP) etching with silicon oxide or silicon nitride as hard mask. Then a passivation layer 407 is formed by, but not limited to, dielectric stakes such as AlN/SiNx, AlN/SiO₂, SiNx/SiO₂, etc. The ohmic contact windows are opened by, but not limited to, ICP etching. A plurality of source, drain, and gate terminals are required to be deposited above the barrier layer 426 above the ohmic contact windows. In certain embodiments, a plurality of ohmic contacts are deposited above the barrier layer 426 to form an LS drain electrode 403A, an LS source electrode 401, an HS drain electrode 405, an HS source electrode 403B, and an auxiliary voltage clamping node 310. The LS gate electrode 402 is also formed between the LS drain electrode 403A and the LS source electrode 401. The HS gate electrode 404 is also formed between the HS drain electrode 405 and the HS source electrode 403B. Then planar isolation using ion implantation (of nitrogen, oxygen, or fluorine) and gate contact (Schottky or ohmic) formation as marked by the LS gate electrode 402 and the HS gate electrode 404 are performed.

In order to achieve an intrinsic avalanche capability, the present disclosure provides a plurality of diodes formed in a back-to-back manner in the EBUS substrate 460. In particular, the P-type silicon layer is required to be segmented into a plurality of silicon islands. This is achieved by performing trench etching from the barrier layer 426 to a predetermined depth exceeding the P-type silicon layer to form a first isolation structure 413 and a second isolation structure 412. The etched trench in the first isolation structure 413 and the second isolation structure 412 are passivated with dielectric materials (e.g., oxide, nitride, polyimide, benzocyclobutene (BCB), etc.) at the bottom and along the sidewalls. The first isolation structure 413 is positioned between the LS drain electrode 403A and the HS source electrode 403B, and the second isolation structure 412 is positioned between the HS drain electrode 405 and the auxiliary voltage clamping node 310. The first isolation structure 413 and the second isolation structure 412 are filled with a dielectric material (e.g., oxide, nitride, or polyimide, BCB, etc.), and the first isolation structure 413 and the second isolation structure 412 are connected to the low potential terminal 333. Finally, a plurality via holes 442A-C are formed by photolithography and etching. A metal layer is further deposited into the plurality via holes 442A-C by using, but not limited to, sputtering technique or electroplating, so as to establish electrical conductivity from the plurality of silicon islands to the LS source electrode 401, the HS source electrode 403B, and the auxiliary voltage clamping node 310. It is noted that via holes 442A-C may also be formed before the fabrication of the isolation structures 411, 412, 413. In order to allow the semiconductor structure to function as a half-bridge circuit 300, the LS drain electrode 403A and the HS source electrode 403B are connected together as a switching terminal (V_{SW}) 332 of the half-bridge circuit 300; the LS source electrode 401 is connected to a low potential terminal 333; and the HS drain electrode 405 and the auxiliary voltage clamping node 310 are connected together to an input terminal (V_{IN}) 331 of the half-bridge circuit 300.

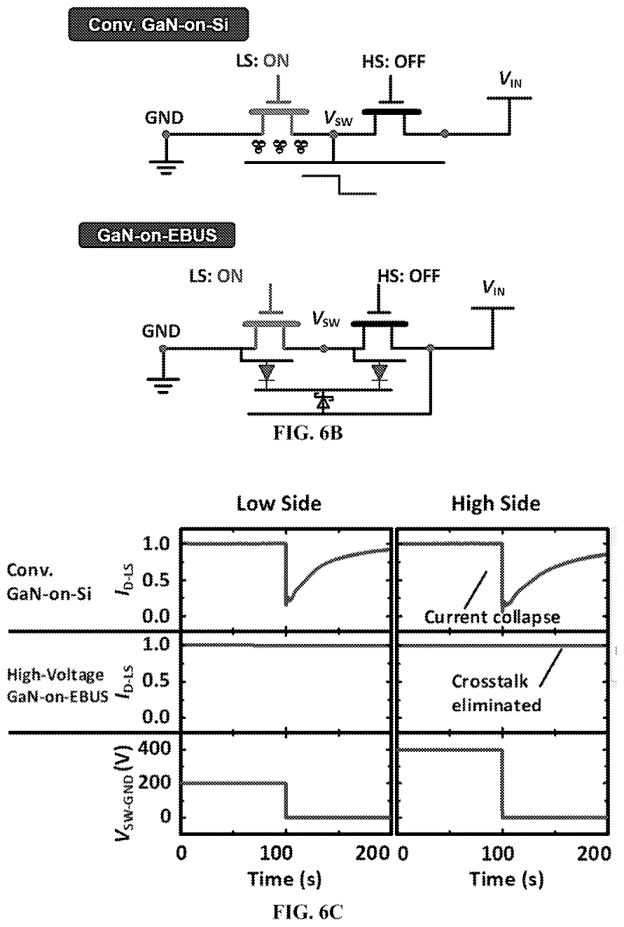

FIG. 6A shows a comparison between the conventional half-bridge circuit and the present invention in the circuit level when the HS transistor 321 is ON and the LS transistor 322 is OFF. When the HS transistor 321 is ON, the input terminal (V_{IN}) 331 is connected to the switching terminal (V_{SW}) 332. Moving onto FIG. 6B, when the HS transistor 321 is changed to OFF and the LS transistor 322 is changed to ON, the charges at the switching terminal (V_{SW}) 332 are accumulated in the conventional half-bridge circuit causing crosstalk effects. In contrast, the present invention has diodes arranged in a back-to-back manner, which can quickly discharge the charges to eliminate the crosstalk between the HS transistor 321 and the LS transistor 322. The performance in crosstalk elimination is illustrated in FIG. 6C. In the conventional half-bridge circuit, as the common substrate is terminated to the source of HS transistor 321, the potential differences between V_{SW} and GND (i.e., V_{SW-GND}=V_{GND}−V_{SW}) cause a positive substrate-to-source voltage to the LS transistor 322 at OFF-state due to buffer trapping when the LS transistor 322 is switched from OFF-state to ON-state. In comparison, I_{D} of the LS transistor 322 (I_{D-LS}) stays intact on the EBUS substrate 460.

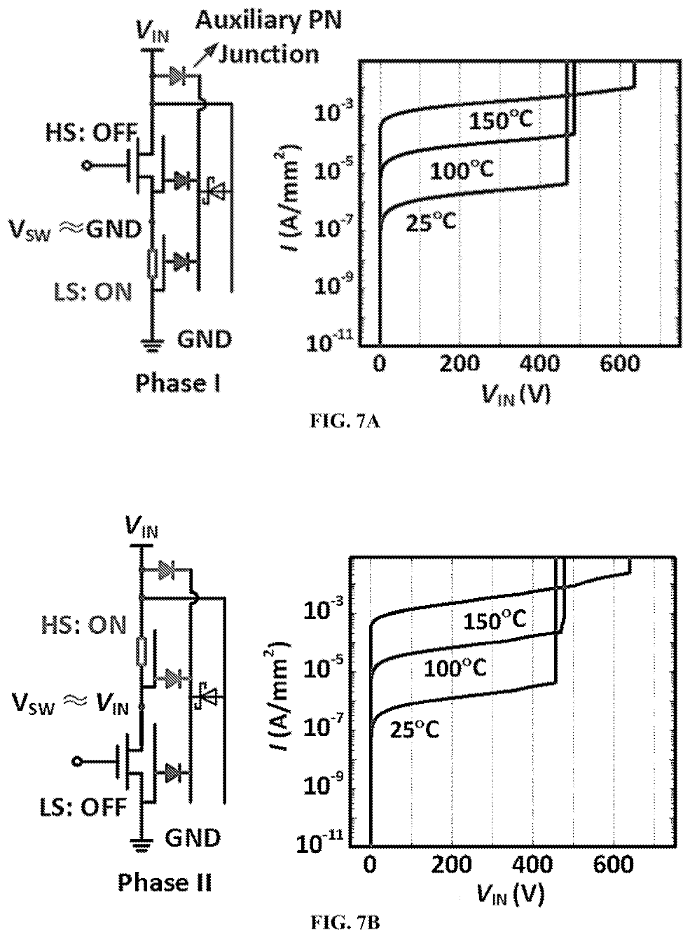

Referring to FIG. 7A, the circuit diagram of the half-bridge circuit and the corresponding current-voltage (I-V) curve are shown during phase I when the HS transistor 321 is OFF and the LS transistor 322 is ON. In phase I, the two PN junctions have a blocking voltage. Referring to FIG. 7B, the circuit diagram of the half-bridge circuit and the corresponding I-V curve are shown during phase II when the HS transistor 321 is ON and the LS transistor 322 is OFF. In phase II, only one PN junction has a blocking voltage. The avalanche breakdown of the PN junction is provided in phase II.

In phase I, the breakdown voltage at room temperature is measured to be 460V, which is dominated by the back-to-back PN junctions of the clamping diode 351 and the second diode 352. In phase II, the breakdown voltage at room temperature is measured to be 450V, which is dominated by the back-to-back PN junctions of the first diode 353 and the second diode 352. The sharp current rise and positive temperature coefficient of the breakdown voltage when the temperature increases from 25° C. to 150° C., which reveals the avalanche-dominated breakdown of the back-to-back PN junctions. Since the avalanche breakdown occurs at a voltage below the BV of the GaN transistor, the avalanche capability of the PN junction pairs is made available to provide overvoltage protection on an EBUS substrate with a sufficient safe margin.

In both two phases, the clamping diode 351 is not reverse-biased and provides a flow path of avalanche current for the HS transistor 321. Meanwhile, the back-to-back PN junctions of the first diode 353 and the second diode 352 are not conducting load current, as there is always one PN diode being reverse-biased, and therewith poor reverse recovery issues are avoided.

This illustrates a GaN on an EBUS substrate with intrinsic avalanche capability enabled by built-in Si PN junctions in accordance with the present disclosure. It will be apparent that variants of the above-disclosed and other features and functions, or alternatives thereof, may be integrated into other semiconductor devices. The present embodiment is, therefore, to be considered in all respects as illustrative and not restrictive. The scope of the disclosure is indicated by the appended claims rather than by the preceding description, and all changes that come within the meaning and range of equivalency of the claims are therefore intended to be embraced therein.

### LIST OF REFERENCES

There follows a list of references that are occasionally cited in the specification. Each of the disclosures of these references is incorporated by reference herein in its entirety.
[1] K. J. Chen, J. Wei, G. Tang, H. Xu, Z. Zheng, L. Zhang, and W. Song, “Planar GaN Power Integration—the World is Flat.” in IEDM Tech. Dig., San Francisco, CA, USA, December 2020, pp. 27.1. 1-27.1.4, doi: 10.1109/IEDM13553.2020.9372069.
[2] S. Ujita, Y. Kinoshita, H. Umeda, T. Morita, S. Tamura, M. Ishida, and T. Ueda, “A Compact GaN-based DC-DC Converter IC with High-speed Gate Drivers Enabling High Efficiencies.” in Proc. ISPSD, Waikoloa, HI, USA, June 2014, pp. 51-54, doi: 10.1109/ISPSD.2014.6855973.
[3] G. Tang, M.-H. Kwan, Z. Zhang, J. He, J. Lei, R.-Y. Su, F.-W. Yao, Y.-M. Lin, J.-L. Yu, and T. Yang, “High-speed, High-Reliability GaN Power Device with Integrated Gate Driver.” in Proc. ISPSD, Chicago, IL, USA, May 2018, pp. 76-79, doi: 10.1109/ISPSD.2018.8393606.
[4] B. Weiss, R. Reiner, V. Polyakov, P. Waltereit, R. Quay, O. Ambacher, and D. Maksimović, “Substrate Biasing Effects in a High-voltage, Monolithically-Integrated Half-Bridge GaN-Chip.” in Proc. IEEE 5th Workshop on Wide Bandgap Power Devices and Applications (WiPDA), Albuquerque, NM, USA, 30 Oct.-1 Nov. 2017, pp. 265-272, doi: 10.1109/WiPDA.2017.8170558.
[5] J. Wei, M. Zhang, G. Lyu, and K. J. Chen, “GaN Integrated Bridge Circuits on Bulk Silicon Substrate: Issues and Proposed Solution,” IEEE J. Electron Devices Soc., vol. 9, pp. 545-551, May 2021, doi: 10.1109/jeds.2021.3077273.
[6] Q. Jiang, C. Liu, Y. Lu and K. J. Chen, “1.4-kV AlGaN/GaN HEMTs on a GaN-on-SOI Platform,” IEEE Electron Device Letters, vol. 34, no. 3, pp. 357-359, March 2013, doi: 10.1109/LED.2012.2236637.
[7] R. K. Williams, M. N. Darwish, R. A. Blanchard, R. Siemieniec, P. Rutter, and Y. Kawaguchi, “The Trench Power MOSFET—Part II: Application Specific VDMOS, LDMOS, Packaging, and Reliability,” IEEE Trans. Electron Devices, vol. 64, no. 3, pp. 692-712, February 2017, doi: 10.1109/ted.2017.2655149.

What is claimed is:

1. A semiconductor device, comprising:
an engineered bulk silicon (EBUS) substrate comprising a first silicon layer and a second silicon layer formed above the first silicon layer; and
a semiconductor heterostructure formed above the EBUS substrate, wherein the semiconductor heterostructure comprises a high-side (HS) transistor and a low-side (LS) transistor,
wherein:
the HS transistor and the LS transistor are separated by a first isolation structure;
the HS transistor has an input terminal (V_{IN}) electrically connected to a clamping diode formed at a first heterojunction between the first and second silicon layers; and
the clamping diode and the HS transistor are separated by a second isolation structure.

2. The semiconductor device of claim 1, wherein the first and second isolation structures divide the second silicon layer into a first silicon island positioned under the LS transistor, a second silicon island positioned under the HS transistor, and a third silicon island not overlying with the HS transistor.

3. The semiconductor device of claim 2, wherein:
a first diode is formed at a second heterojunction between the first silicon island and the first silicon layer;
a second diode is formed at a third heterojunction between the second silicon island and the first silicon layer; and
the clamping diode is formed between the third silicon island and the first silicon layer.

4. The semiconductor device of claim 3, wherein the third silicon island is electrically connected to the input terminal (V_{IN}) at an auxiliary voltage clamping node by a third via hole for protecting the HS transistor, wherein the auxiliary voltage clamping node is connected to an HS drain electrode of the HS transistor.

5. The semiconductor device of claim 3, wherein:
the first silicon island is electrically connected to a low potential terminal by a first via hole;
the second silicon island is electrically connected to a switching terminal (V_{SW}) by a second via hole; and
the first diode and the second diode are arranged between the switching terminal (V_{SW}) and the low potential terminal in a back-to-back manner to provide an avalanche breakdown function.

6. The semiconductor device of claim 3, wherein the first silicon layer is an N-type silicon layer; and the second silicon layer is a P-type silicon layer.

7. The semiconductor device of claim 2, wherein the first and the second isolation structures are deep trench isolation structures filled with dielectric materials, wherein the deep trench isolation structures are extended vertically deep enough to at least divide the second silicon layer into the first silicon island, the second silicon island, and the third silicon island.

8. The semiconductor device of claim 7, wherein the first and the second isolation structures each has a depth and a width tuned to modulate an avalanche breakdown voltage, wherein the depth and the width affect a crowded electrical field along isolation trench sidewalls.

9. The semiconductor device of claim 1, wherein the EBUS substrate further comprises a dielectric layer provided below the first silicon layer.

10. The semiconductor device of claim 1, wherein the EBUS substrate further comprises a mechanical substrate provided below the first silicon layer, wherein a Schottky contact is formed between the mechanical substrate and the first silicon layer.

11. The semiconductor device of claim 1, wherein the EBUS substrate further comprises a third silicon layer formed at a backside of the first silicon layer, thereby a PNP doping profile is formed from the second silicon layer to the third silicon layer, and wherein the third silicon layer is a P-type silicon layer.

12. The semiconductor device of claim 1, wherein the semiconductor heterostructure is an III-N semiconductor heterostructure comprising a transition layer, a buffer layer, and a barrier layer, wherein:
the buffer layer is formed on and adjacent to the transition layer;
the barrier layer is formed on and adjacent to the buffer layer; and
the buffer layer and the barrier layer form a heterojunction, wherein the buffer layer has a channel layer including a 2-dimensional electron gas (2DEG) channel formed near an interface between the barrier layer and the buffer layer.

13. The semiconductor device of claim 12, wherein the transition layer is a Gallium Nitride (GaN) layer and the buffer layer is an Aluminium Gallium Nitride (AlGaN) layer.

14. The semiconductor device of claim 12, wherein:
a plurality of ohmic contacts are deposited above the barrier layer to form an LS drain electrode, an LS source electrode, an HS drain electrode, an HS source electrode, and an auxiliary voltage clamping node; and
the auxiliary voltage clamping node is electrically connected to the HS drain electrode and is not overlying with the HS transistor for protecting the HS transistor by providing an over voltage protection through the clamping diode positioned below the auxiliary voltage clamping node.

15. The semiconductor device of claim 1, wherein the semiconductor heterostructure is a standalone heterostructure transistor or a monolithic integrated heterostructure transistor.

16. A method for fabricating a semiconductor device having an III-N semiconductor heterostructure formed above an engineered bulk silicon (EBUS) substrate with an intrinsic avalanche capability, the method comprising:
depositing a mechanical substrate on a backside of an N-type silicon layer;
forming a P-type silicon layer above the N-type silicon layer by performing boron implantation into the N-type silicon layer or by performing Si epitaxial deposition;
depositing a transition layer of an III-N semiconductor material above the P-type silicon layer;
depositing a buffer layer of Aluminium Gallium Nitride (AlGaN) above the transition layer by performing metal-organic chemical vapor deposition;
depositing a barrier layer above the buffer layer;
depositing a plurality of ohmic contacts above the barrier layer to form a low-side (LS) drain electrode, an LS source electrode, a high-side (HS) drain electrode, an HS source electrode, and an auxiliary voltage clamping node;
performing etching from the barrier layer to a predetermined depth exceeding the P-type silicon layer to form a first isolation structure and a second isolation structure for segmenting the P-type silicon layer into a plurality of silicon islands, wherein the first isolation structure is positioned between the LS drain electrode and the HS source electrode, and the second isolation structure is positioned between the HS drain electrode and the auxiliary voltage clamping node;
filling the first isolation structure and the second isolation structure with a dielectric material; and
forming a plurality via holes to establish electrical conductivity from the plurality of silicon islands to the LS source electrode, the HS source electrode, and the auxiliary voltage clamping node.

17. The method of claim 16, wherein the forming the P-type silicon layer above the N-type silicon layer further comprises performing high-temperature annealing process and thermal diffusion or epitaxy growth to re-distribute dopants of boron throughout the P-type silicon layer.

18. The method of claim 16 further comprising:
connecting the LS drain electrode and the HS source electrode together as a switching terminal (V_{SW}) of a half-bridge circuit;
connecting the LS source electrode to a low potential terminal; and
connecting the HS drain electrode and the auxiliary voltage clamping node together to an input terminal (V_{IN}) of the half-bridge circuit.
